(19) United States
(12) Patent Application Publication
(10) Pub. No.: US 2022/0181531 A1
(43) Pub. Date: Jun. 9, 2022

(54) DISPLAY MODULE, MANUFACTURING METHOD THEREOF, AND ELECTRONIC DEVICE

(71) Applicant: CHONGQING KONKA PHOTOELECTRIC TECHNOLOGY RESEARCH INSTITUTE CO., LTD., Chongqing (CN)

(72) Inventor: Tao WANG, Chongqing (CN)

(21) Appl. No.: 17/569,924

(22) Filed: Jan. 6, 2022

Related U.S. Application Data
(63) Continuation of application No. PCT/CN2020/134585, filed on Dec. 8, 2020.

(51) Int. Cl. H01L 33/62; H01L 27/15; H01L 33/00; H01L 33/10; H01L 33/38

(52) U.S. Cl. CPC H01L 33/62; H01L 27/156; H01L 2933/0066; H01L 33/10; H01L 33/38; H01L 33/005

(57) ABSTRACT

A display module, a manufacturing method thereof, and an electronic device are provided. The manufacturing method includes the followings. A back plate is provided and a first sub-metal layer is formed on the back plate. An epitaxial structure is provided, where the epitaxial structure includes a substrate and a semiconductor structure disposed on the substrate. A planarization layer is formed on a side of the semiconductor structure away from the substrate, and the planarization layer is patterned. A second sub-metal layer is formed on the planarization layer, where the second sub-metal layer is electrically connected with the semiconductor structure through each of multiple first via holes. The epitaxial structure and the back plate are bonded through the first sub-metal layer and the second sub-metal layer, and the substrate is removed. The semiconductor structure is patterned to form multiple light-emitting units separated from one another.

### CROSS-REFERENCE TO RELATED APPLICATIONS

This application is a continuation of International Application No. PCT/CN2020/134585, filed on Dec. 8, 2020, the entire disclosure of which is incorporated herein by reference.

### TECHNICAL FIELD

This disclosure relates to the technical field of display, and in particular to a display module, a manufacturing method thereof, and an electronic device.

### BACKGROUND

For an existing display module, light-emitting units such as light-emitting diodes (LEDs), micro LEDs, and mini LEDs are usually prepared at first, and then the light-emitting units are welded to a back-plate circuit (a circuit board) through mass transfer to form a display module with multiple light-emitting units arranged in an array. During the mass transfer, due to a small size of a light-emitting unit, especially a micro LED, it is easy to cause low alignment accuracy. In addition, an existing light-emitting unit has low light emitting efficiency.

Therefore, problems of low alignment accuracy during the mass transfer and low light emitting efficiency of the light-emitting units are urgent to be solved.

### SUMMARY

In a first aspect, a manufacturing method of a display module is provided in implementations of the present disclosure, and the method includes the followings. A back plate is provided and a first sub-metal layer is formed on the back plate. An epitaxial structure is provided, where the epitaxial structure includes a substrate and a semiconductor structure disposed on the substrate. A planarization layer is formed on a side of the semiconductor structure away from the substrate, and the planarization layer is patterned to form multiple first via holes penetrating through the planarization layer. A second sub-metal layer is formed on the planarization layer, where the second sub-metal layer is electrically connected with the semiconductor structure through each of the multiple first via holes. The epitaxial structure and the back plate are bonded through the first sub-metal layer and the second sub-metal layer, and the substrate in a bonded epitaxial structure is removed. The semiconductor structure is patterned to form multiple light-emitting units separated from one another, where a projection of one light-emitting unit on the back plate overlaps with a projection of one first via hole on the back plate.

In a second aspect, a display module is also provided in implementations of the present disclosure. The display module includes a back plate and multiple light-emitting units. The multiple light-emitting units are disposed on a surface of the back plate in an array. Each of the multiple light-emitting units includes a metal reflection portion, a planarization portion, and a semiconductor structure portion stacked on the back plate in sequence. The semiconductor structure portion is electrically connected with the metal reflection portion through a first via hole penetrating through the planarization portion.

In a third aspect, an electronic device is also provided in implementations of the present disclosure. The electronic device includes a display module. The display module includes a back plate and multiple light-emitting units. The multiple light-emitting units are disposed on a surface of the back plate in an array. Each of the multiple light-emitting units includes a metal reflection portion, a planarization portion, and a semiconductor structure portion stacked on the back plate in sequence. The semiconductor structure portion is electrically connected with the metal reflection portion through a first via hole penetrating through the planarization portion.

### BRIEF DESCRIPTION OF THE DRAWINGS

In order to explain technical solutions in implementations of the present disclosure more clearly, the following will give a brief introduction to accompanying drawings needed to be used in description of the implementations or the related art. Apparently, the accompanying drawings in the following description are merely some implementations of the present disclosure. For those of ordinary skill in the art, other accompanying drawings can be obtained according to these accompanying drawings without creative efforts.

FIG. 1 is a schematic flowchart illustrating a manufacturing method of a display module provided in implementations of the present disclosure.

FIG. 2 is a flowchart illustrating a manufacturing method of a display module provided in implementations of the present disclosure.

FIG. 3 is a schematic flowchart illustrating a manufacturing method of a display module provided in other implementations of the present disclosure.

FIG. 4 is a flowchart illustrating a manufacturing method of a display module provided in other implementations of the present disclosure.

FIG. 5 is a schematic cross-sectional structural view illustrating a display module provided in implementations of the present disclosure.

FIG. 6 is a schematic cross-sectional structural view illustrating a display module provided in other implementations of the present disclosure.

FIG. 7 is a schematic top structural view illustrating the display module provided in the implementation of FIG. 6 of the present disclosure.

FIG. 8 is a schematic structural view illustrating an electronic device provided in implementations of the present disclosure.

Description of reference signs of the accompanying drawings: 300—display module; 310—back plate; 301—first via hole; 311—first sub-metal layer; 312—first electrode; 314—second electrode; 330—epitaxial structure; 331—substrate; 333—semiconductor structure; 3331—first semiconductor layer; 3333—light-emitting layer; 3335—second semiconductor layer; 350—light-emitting unit; 351—metal reflection portion; 353—planarization portion; 355—semiconductor structure portion; 35a—first semiconductor portion; 35b—light-emitting portion; 35c—second semiconductor portion; 357—ohmic contact portion; 332—second sub-metal layer; 334—planarization layer; 336—ohmic contact layer; 370—insulating protection layer; 390—conductive layer; 400—electronic device.

### DETAILED DESCRIPTION

In order to make purposes, technical solutions, and advantages of the present disclosure clearer, the present disclosure is further described in detail below in combination with accompanying drawings and implementations. It should be understood that the specific implementations described herein are only used to explain the present disclosure and are not used to limit the present disclosure.

In description of the present disclosure, it should be understood that locations or positional relationships indicated by terms such as “center”, “longitudinal”, “lateral”, “length”, “width”, “thickness”, “on”, “under”, “front”, “back”, “left”, “right”, “vertical”, “horizontal”, “top”, “bottom”, “in”, “out”, “clockwise”, “anticlockwise”, and the like are locations or positional relationships based on the accompanying drawings and are only for the convenience of description and simplicity, rather than explicitly or implicitly indicate that apparatuses or components referred to herein must have a certain direction or be configured or operated in a certain direction and therefore cannot be understood as limitations to the present disclosure. In addition, terms “first”, “second”, and the like are only used for description and cannot be understood as explicitly or implicitly indicating relative importance or implicitly indicating the number of technical features referred to herein. Therefore, features limited by terms “first”, “second”, and the like can explicitly or implicitly include at least one of the features. In the context of the present disclosure, unless stated otherwise, “multiple” or “a plurality of” refers to at least two.

In description of the present disclosure, it should be noted that, unless stated otherwise, terms “installing”, “coupling”, and “connecting” referred to herein should be understood in broader sense. For example, they may include a fixed coupling, a removable coupling, or an integrated coupling; they may include a mechanical coupling or an electrical coupling; they may include a direct coupling, an indirect coupling through a medium, or an interconnection between two components or an interaction between two components. For those of ordinary skill in the art, the above terms in the present disclosure can be understood according to specific situations.

For an existing display module, light-emitting units such as light-emitting diodes (LEDs), micro LEDs, and mini LEDs are usually prepared at first, and then the light-emitting units are welded to a back-plate circuit (a circuit board) through mass transfer to form a display module with multiple light-emitting units arranged in an array. During the mass transfer, due to a small size of a light-emitting unit, especially a micro LED, it is easy to cause low alignment accuracy. In addition, due to the small size of the light-emitting unit, an existing light-emitting unit has low light emitting efficiency.

Based on this, the present disclosure provides a solution that can solve the above technical problems, and its details will be described in subsequent implementations.

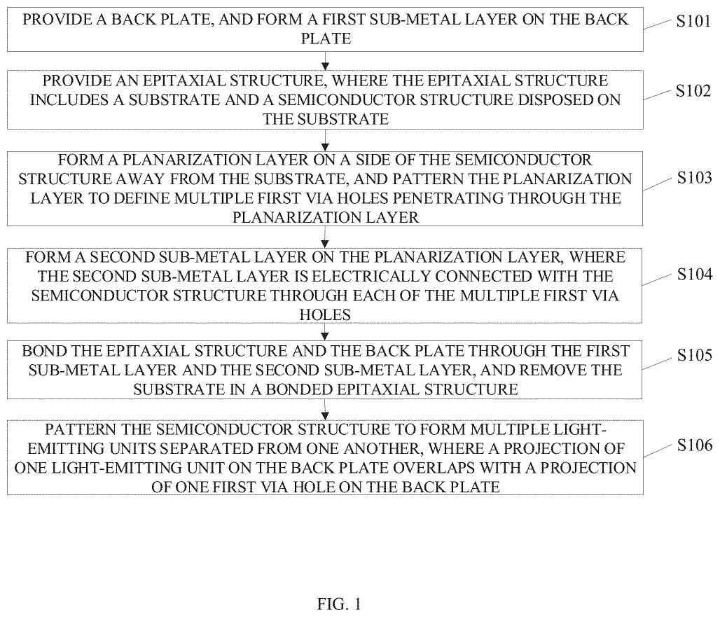

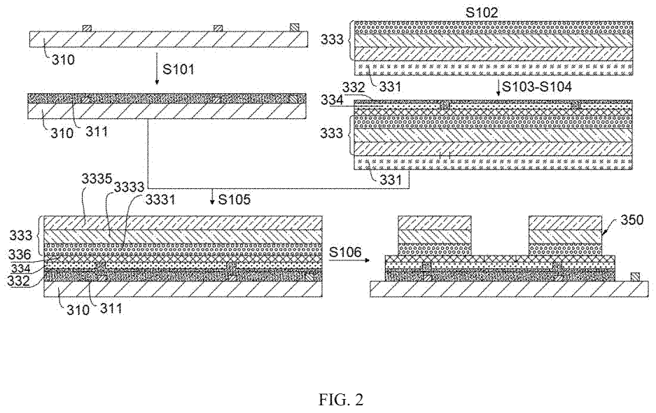

Reference can be made to FIG. 1 and FIG. 2, and a manufacturing method of a display module 300 provided in a first aspect of a first implementation of the present disclosure includes the followings.

S101, a back plate 310 is provided, and a first sub-metal layer 311 is formed on the back plate 310.

Optionally, the back plate 310 is an under bump metallurgy (UBM) back plate 310. The first sub-metal layer 311 includes, but is not limited to, a chromium (Cr) layer, a platinum (Pt) layer, and an aurum (Au) layer stacked in sequence.

Optionally, the first sub-metal layer 311 may be, but is not limited to, prepared by sputtering, evaporation, etc.

S102, an epitaxial structure 330 is provided, where the epitaxial structure 330 includes a substrate 331 and a semiconductor structure 333 disposed on the substrate 331.

Optionally, the substrate 331 may be, but is not limited to, made of gallium arsenide (GaAs).

Optionally, the semiconductor structure 333 includes a first semiconductor layer 3331, a light-emitting layer 3333, and a second semiconductor layer 3335 which are stacked in sequence. The second semiconductor layer 3335 is disposed closer to the substrate 331 than the first semiconductor layer 3331. In an implementation, the first semiconductor layer 3331 is a P-type semiconductor layer, the second semiconductor layer 3335 is a N-type semiconductor layer, and the light-emitting layer 3333 may be, but is not limited to, a double heterostructure (DH) or a quantum well structure. Optionally, the light-emitting layer 3333 may be, but is not limited to, made of one or more of: aluminium gallium indium phosphide (AlGaInP), indium gallium phosphide (InGaP), gallium nitride (GaN), aluminium gallium nitride (AlGaN), indium gallium nitride (InGaN), and aluminium gallium indium nitride (AlGaInN).

S103, a planarization layer 334 is formed on a side of the semiconductor structure 333 away from the substrate 331, and the planarization layer 334 is patterned to define multiple first via holes 301 penetrating through the planarization layer 334.

Optionally, the planarization layer 334 may be, but is not limited to, an inorganic insulating layer. The inorganic insulating layer may be, but is not limited to, made of silicon dioxide (SiO₂), silicon nitride (SiNx), silicon monoxide (SiO), and titanium dioxide (TiO₂), which is not limited in the present disclosure. When the planarization layer 334 is made of SiO₂, adhesion force between a following second sub-metal layer 332 and a following ohmic contact layer 336 can also be increased to prevent an omni-directional reflector (ODR) formed by the planarization layer 334 and the following second sub-metal layer 332 from peeling. In addition, the planarization layer 334 can also reduce unevenness of a surface of the following second sub-metal layer 332.

Optionally, the planarization layer 334 can be prepared by plasma enhanced chemical vapor deposition (PECVD).

Optionally, the planarization layer 334 can be etched by a first photolithography process, an etching technology, etc. to define the multiple first via holes 301 on the planarization layer 334 in an array. Specifically, a photolithography includes, but is not limited to, spin coating, exposure, developing, etc.

S104, a second sub-metal layer 332 is formed on the planarization layer 334, where the second sub-metal layer 332 is electrically connected with the semiconductor structure 333 through each of the multiple first via holes 301.

Optionally, the second sub-metal layer 332 is prepared on a surface of the planarization layer 334 away from the substrate 331 by the evaporation, the sputtering, etc., and the multiple first via holes 301 are filled with the second sub-metal layer 332, such that the second sub-metal layer 332 is electrically connected with the first semiconductor layer 3331 (the P-type semiconductor layer) of the semiconductor structure 333.

The second sub-metal layer 332 includes multiple metal layers stacked in sequence. In a specific implementation, a second sub-metal layer 332 includes a Cr layer, a Pt layer, and an Au layer stacked in sequence. By adopting the Cr layer, the Pt layer, and the Au layer as the second sub-metal layer 332, the second sub-metal layer 332 and the planarization layer 334 form the ODR to reflect back more light emitted to the second sub-metal layer 332, which makes the display module 300 have a better light extraction rate.

It should be understood that, there is no order between S101 and S102-S104, and S101 can be performed before S102, or S101 can also be performed after S104.

S105, the epitaxial structure 330 and the back plate 310 are bonded through the first sub-metal layer 311 and the second sub-metal layer 332, and the substrate 331 in a bonded epitaxial structure 330 is removed.

Specifically, the epitaxial structure 330 and the back plate 310 are bonded by metallic bonding through the first sub-metal layer 311 and the second sub-metal layer 332, and then the substrate 331 in the bonded epitaxial structure 330 is removed by a wet etching process. Exemplarily, the metallic bonding may include the followings. Firstly, the back plate 310 with the first sub-metal layer 311 is pre-aligned with the epitaxial structure 330 with the second sub-metal layer 332, appropriate pressure is applied to the epitaxial structure 330 or the back plate 310 through a bonding apparatus (not illustrated in the accompanying drawings), and then the back plate 310 and the epitaxial structure 330 are put into an annealing furnace for annealing. Annealing can be performed in a preset protection atmosphere, and a heating rate, an annealing temperature, annealing time, a cooling rate, etc. can be set. During annealing, diffusion, mutual melting, etc. occur between metals and between metals and semiconductors, such that metals and metals, metals and semiconductors are firmly bonded together by metallic bond, covalent bond, hydrogen bond, van der Waals force, melting fluid force, or atomic diffusion, etc.

S106, the semiconductor structure 333 is patterned to form multiple light-emitting units 350 separated from one another, where a projection of one light-emitting unit 350 on the back plate 310 overlaps with a projection of one first via hole 301 on the back plate 310.

Specifically, the photolithographic process and a mesa etching method are used for etching to form the multiple light-emitting units 350 which are arranged in an array and on a side of the back plate 310.

In the manufacturing method of the display module 300 provided in the present disclosure, the semiconductor structure 333 and the back plate 310 are bonded through the first sub-metal layer 311 and the second sub-metal layer 332, and then are patterned to form the multiple light-emitting units 350, such that the mass transfer is avoided, thereby effectively avoiding a problem of low alignment accuracy during the mass transfer. At the same time, the second sub-metal layer 332 and the planarization layer 334 form the ODR to reflect back more light emitted to the second sub-metal layer 332, which makes the display module 300 have a better light extraction rate.

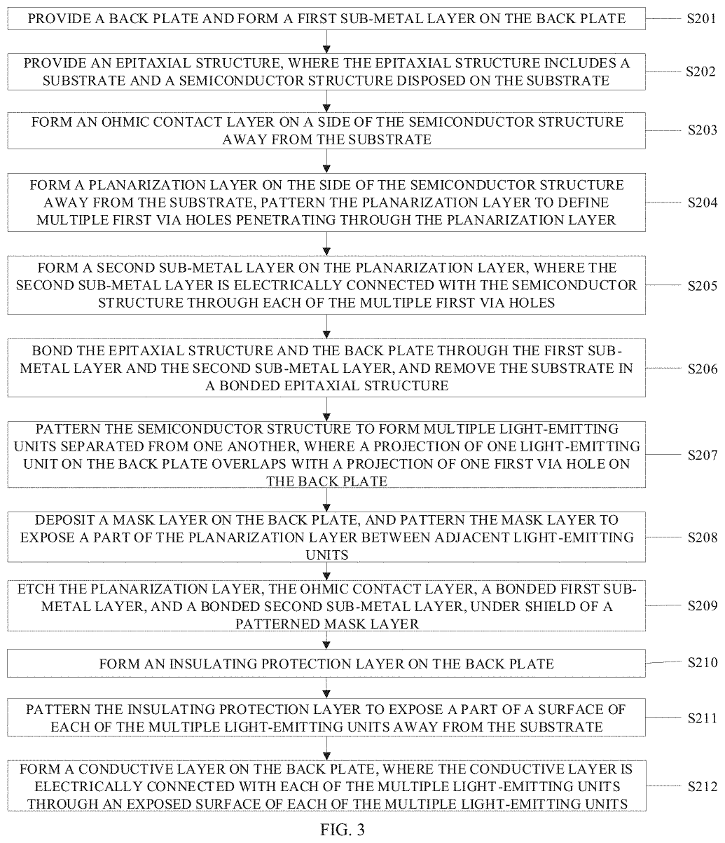

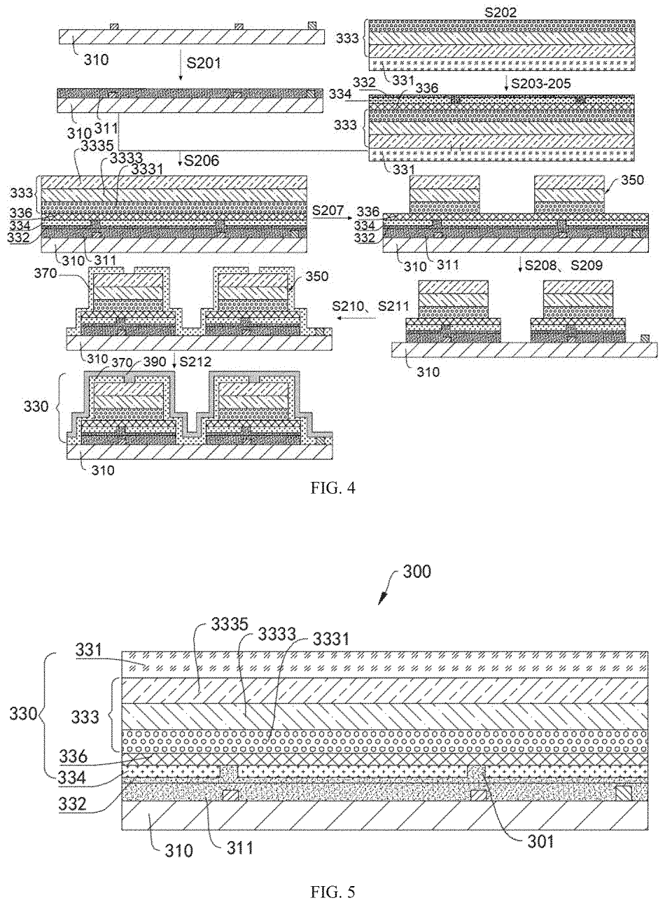

Reference can be made to FIG. 3 and FIG. 4, and a manufacturing method of a display module 300 provided in the first aspect of a second implementation of the present disclosure includes the followings.

S201, a back plate 310 is provided, and a first sub-metal layer 311 is formed on the back plate 310.

S202, an epitaxial structure is provided, where the epitaxial structure 330 includes a substrate 331 and a semiconductor structure 333 disposed on the substrate 331.

As for parts of 5201 and 5202 that are the same as those in the first implementation, please refer to description of the above first implementation, which will not be repeated here.

S203, an ohmic contact layer 336 is formed on a side of the semiconductor structure 333 away from the substrate 331.

Specifically, the ohmic contact layer 336 is formed on a surface of the first semiconductor layer 3331 of the semiconductor structure 333 away from the substrate 331.

Specifically, the ohmic contact layer 336 may be an indium tin oxide (ITO) layer. Due to the ohmic contact layer 336, an ohmic contact is formed between the first semiconductor layer 3331 and a following second sub-metal layer 332, which facilitates input and output of a current, and can effectively reduce an impedance between the second sub-metal layer 332 and the first semiconductor layer 3331.

S204, a planarization layer 334 is formed on a side of the ohmic contact layer 336 away from the substrate 331, and the planarization layer 334 is patterned to define multiple first via holes 301 penetrating through the planarization layer 334.

S205, a second sub-metal layer 332 is formed on the planarization layer 334, where the second sub-metal layer 332 is electrically connected with the semiconductor structure 333 through each of the multiple first via holes 301.

It should be understood that, there is no order between 5201 and S202-S205, and 5201 can be performed before 5202, or it can also be performed after S205.

S206, the epitaxial structure 330 and the back plate 310 are bonded through the first sub-metal layer 311 and the second sub-metal layer 332, and the substrate 331 in a bonded epitaxial structure 330 is removed.

S207, the semiconductor structure 333 is patterned to form multiple light-emitting units 350 separated from one another, where a projection of one light-emitting unit 350 on the back plate 310 overlaps with a projection of one first via hole 301 on the back plate 310.

As for parts of S204-S207 that are the same as those in the first implementation, please refer to description of the above first implementation, which will not be repeated here.

S208, a mask layer is deposited on the back plate 310, and the mask layer is patterned to expose a part of the planarization layer 334 between adjacent light-emitting units 350.

S209, under shield of a patterned mask layer, the planarization layer 334, the ohmic contact layer 336, a bonded first sub-metal layer 311, and a bonded second sub-metal layer 332 are etched.

S210, an insulating protection layer 370 is formed on the back plate 310, where the insulating protection layer 370 covers the multiple light-emitting units 350, the planarization layer 334, and a second sub-metal layer 332.

Optionally, the insulating protection layer 370 may be an inorganic insulating layer, and inorganic insulating layer may be, but is not limited to, a SiO₂ layer, which is not be limited in the present disclosure.

Optionally, the insulating protection layer 370 may be, but is not limited to, prepared by PECVD.

S211, the insulating protection layer 370 is patterned to expose a part of a surface of each of the multiple light-emitting units 350 away from the back plate 310.

Specifically, the insulating protection layer 370 can be etched by a first photolithography process and an etching technology.

S212, a conductive layer 390 is formed on the back plate 310, where the conductive layer 390 is electrically connected with each of the multiple light-emitting units 350 through an exposed surface of each of the multiple light-emitting units 350.

Specifically, the conductive layer 390 is prepared on a surface of the insulating protection layer 370 away from the back plate 310 by sputtering, evaporation, etc., such that the conductive layer 390 is electrically connected with the multiple light-emitting units 350. The conductive layer 390 includes, but is not limited to, made of one or more of: ITO, cadmium tin oxide (CTO), antimony tin oxide (ATO), zinc oxide (ZnO), and zinc tin oxide (ZTO).

Reference can be made to FIG. 5, and a display module 300 is provided in a second aspect of implementations of the present disclosure. The display module 300 includes a back plate 310 and an epitaxial structure 330. The back plate 310 is provided with a first sub-metal layer 311. The epitaxial structure 330 is provided with a second sub-metal layer 332. The back plate 310 and the epitaxial structure 330 are bonded through the first sub-metal layer 311 and the second sub-metal layer 332. The epitaxial structure 330 further includes a planarization layer 334 and a semiconductor structure 333 disposed on the planarization layer 334, the planarization layer 334 is located on a side of the second sub-metal layer 332 away from the first sub-metal layer 311, and the semiconductor structure 333 is electrically connected with the second sub-metal layer 332 through multiple first via holes 301 penetrating through the planarization layer 334.

In the display module 300 of the present disclosure, the second sub-metal layer 332 and the planarization layer 334 form an ODR to reflect back more light emitted to the second sub-metal layer 332, which makes the display module 300 have a better light extraction rate. At the same time, by bonding the first sub-metal layer 311 and the second sub-metal layer 332, mass transfer is avoided, and thus a problem of low alignment accuracy during the mass transfer is effectively avoided.

Optionally, the planarization layer 334 may be, but is not limited to, an inorganic insulating layer. The inorganic insulating layer may be, but is not limited to, made of SiO₂, SiNx, SiO, and TiO₂, which is not limited in the present disclosure. When the planarization layer 334 is made of SiO₂, adhesion force between a following second sub-metal layer 332 and the ohmic contact layer 336 can also be increased to prevent the ODR formed by the planarization layer 334 and the following second sub-metal layer 332 from peeling. In addition, the planarization layer 334 can also reduce unevenness of a surface of the following second sub-metal layer 332.

Optionally, the first sub-metal layer 311 includes a Cr layer, a Pt layer, and an Au layer stacked in sequence. The second sub-metal layer 332 includes an Au layer, a Pt layer, and a Cr layer stacked in sequence.

Optionally, the semiconductor structure 333 includes a first semiconductor layer 3331, a light-emitting layer 3333, and a second semiconductor layer 3335 which are stacked in sequence. The second semiconductor layer 3335 is disposed farther away from the back plate 310 than the first semiconductor layer 3331. In an implementation, the first semiconductor layer 3331 is a P-type semiconductor layer, the second semiconductor layer 3335 is a N-type semiconductor layer, and the light-emitting layer 3333 may be, but is not limited to, a DH or a quantum well structure. Optionally, the light-emitting layer 3333 may be, but is not limited to, made of one or more of: AlGaInP, InGaP, GaN, AlGaN, InGaN, and AlGaInN.

In some implementations, the display module 300 in implementations of the present disclosure further includes an ohmic contact layer 336. The ohmic contact layer 336 is formed between the planarization layer 334 and the semiconductor structure 333. The semiconductor structure 333 is electrically connected with the second sub-metal layer 332 through the ohmic contact layer 336 and the multiple via holes 301. Due to the ohmic contact layer 336, an ohmic contact is formed between the first semiconductor layer 3331 and the second sub-metal layer 332, which facilitates diffusion of a current, and can effectively reduce an impedance between the second sub-metal layer 332 and the first semiconductor layer 3331.

In some implementations, the display module 300 in implementations of the present disclosure further includes a substrate 331 disposed on a surface of the second semiconductor layer 3335 away from the back plate 310.

As for parts of the display module 300 of this implementation that are the same as the those of implementations in the first aspect of the present disclosure, please refer to the implementations in the first aspect of the present disclosure, which will not be repeated here.

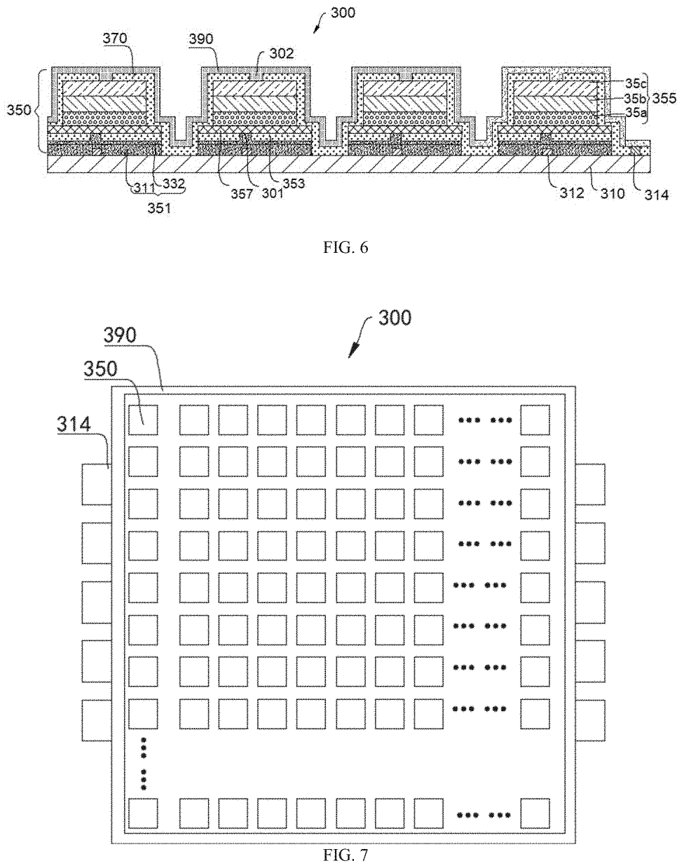

Reference can be made to FIG. 6 and FIG. 7, and a display module 300 is provided in the second aspect of implementations of the present disclosure. The display module 300 includes a back plate 310 and multiple light-emitting units 350. The multiple light-emitting units 350 are disposed on a surface of the back plate 310 in an array. Each of the multiple light-emitting units 350 includes a metal reflection portion 351, a planarization portion 353, and a semiconductor structure portion 355 stacked on the back plate 310 in sequence. The semiconductor structure portion 355 is electrically connected with the metal reflection portion 351 through multiple first via holes 301 penetrating through the planarization portion 353.

In the display module 300 of the present disclosure, the metal reflection portion 351 and the planarization portion 353 form an ODR to reflect back more light emitted to the metal reflection portion 351, which makes the display module 300 have a better light extraction rate.

Optionally, the metal reflection portion 351 includes a first sub-metal layer 311 and a second sub-metal layer 332 stacked in sequence. Optionally, each of the first sub-metal layer 311 and the second sub-metal layer 332 includes, but is not limited to, a Cr layer, a Pt layer, and an Au layer.

Optionally, the planarization portion 353 may be, but is not limited to, an inorganic insulating layer. The inorganic insulating layer may be, but is not limited to, made of SiO₂, SiNx, SiO, and TiO₂, which is not limited in the present disclosure. When the planarization layer 334 is made of SiO₂, adhesion force between a following second sub-metal layer 332 and a following ohmic contact portion 357 can also be increased to prevent an ODR formed by the planarization portion 353 and the following second sub-metal layer 332 from peeling. In addition, the planarization portion 353 can also reduce unevenness of a surface of the following second sub-metal layer 332.

Optionally, the semiconductor structure portion 355 includes a first semiconductor portion 35a, a light-emitting portion 35b, a second semiconductor portion 35c stacked in sequence, and the first semiconductor portion 35a is electrically connected with the metal reflection portion 351.

In an implementations, the first semiconductor portion 35a is a P-type semiconductor portion and configured to generate electron holes. The second semiconductor portion 35c is a N-type semiconductor portion and configured to generate electrons. The light-emitting portion 35b may be, but is not limited to, a single heterostructure (SH), a DH, a double-side double heterostructure (DDH), a multi-quantum well (MQW) structure, or a quantum dots (QDs) structure. The light emitting portion 35b is configured to radiate light with a preset wavelength. When the first semiconductor portion 35a and the second semiconductor portion 35c are powered on, the electron holes generated by the P-type semiconductor portion and the electrons generated by the N-type semiconductor portion move towards the light-emitting portion 35b respectively, and the electron holes and the electrons generate radiation recombination at the light-emitting portion 35b, thereby emitting light.

Optionally, the light-emitting portion 35b may be, but is not limited to, made of one or more of: AlGaInP, InGaP, GaN, AlGaN, InGaN, and AlGaInN.

In some implementations, each of the multiple light-emitting units 350 further includes an ohmic contact portion 357. The ohmic contact portion 357 is formed between the planarization portion 353 and the semiconductor structure portion 355. The semiconductor structure portion 355 is electrically connected with the second sub-metal layer 332 through the ohmic contact portion 357 and the multiple first via holes 301. The ohmic contact portion 357 can reduce an impedance between the metal reflection portion 351 and the first semiconductor portion 35a. Due to the ohmic contact portion 357, an ohmic contact is formed between the the metal reflection portion 351 and the first semiconductor portion 35a, which facilitates input and output of a current, and can effectively reduce an in impedance between the metal reflection portion 351 and the first semiconductor portion 35a.

In some implementations, the display module 300 of the present disclosure further includes an insulating protection layer 370 formed and covering on each of the multiple light-emitting units 350.

In some implementations, the display module 300 of the present disclosure further includes a conductive layer 390. The conductive layer 390 is formed on the insulating protection layer 370 and is electrically connected with each of the multiple light-emitting units 350 through multiple second via holes 302 penetrating through the insulating protection layer 370, and each of the multiple light-emitting units 350 is connected with one another through the conductive layer 390. Optionally, the conductive layer 390 is made of one or more light-transmitting materials including, but are not limited to, ITO, CTO, ATO, ZnO, and ZTO.

Optionally, the back plate 310 includes multiple first electrodes 312 and multiple second electrodes 314, the multiple first electrodes 312 are electrically connected with the metal reflection portion 351, and the multiple second electrodes 314 are electrically connected with the conductive layer 390. Optionally, each of the multiple first electrodes 312 is a P electrode or a positive electrode, and each of the multiple second electrodes 314 is a N electrode or a negative electrode. In some implementations, each of the multiple first electrodes 312 may be, but is not limited to, a conductive metal or a conductive alloy, and each of the multiple second electrodes 314 may be, but is not limited to, the conductive metal or the conductive alloy.

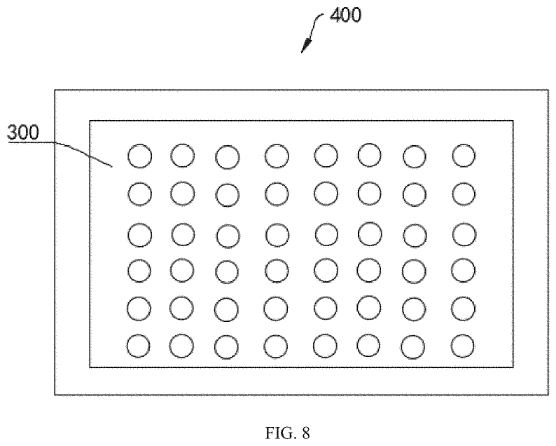

Reference can be made to FIG. 8, and an electronic device 400 is also provided in implementations of the present disclosure. The electronic device 100 includes the display module 300 in implementations of the present disclosure.

Optionally, the display module 300 includes a back plate 310 and multiple light-emitting units 350. The multiple light-emitting units 350 are disposed on a surface of the back plate 310 in an array. Each of the multiple light-emitting units 350 includes a metal reflection portion 351, a planarization portion 353, and a semiconductor structure portion 355 stacked on the back plate 310 in sequence. The semiconductor structure portion 355 is electrically connected with the metal reflection portion 351 through a first via hole 301 penetrating through the planarization portion 353.

The electronic device 400 of the present disclosure includes, but is not limited to, a mobile phone, a tablet computer, a television, a display, a smart watch, a band, an e-reader, a pair of smart glasses, and other electronic devices with a display function.

The reference term “an implementation”, “some implementations”, “exemplary implementation”, “example”, “specific example”, or “some examples” referred to herein means that a particular feature, structure, material, or characteristic described in conjunction with the embodiment or implementation may be contained in at least one embodiment or implementation of the present disclosure. The phrase appearing in various places in the specification does not necessarily refer to the same embodiment or implementation. In addition, the particular feature, structure, material, or characteristic described may be properly combined in any one or more embodiments or implementations.

The above are only preferred implementations of the present disclosure and are not intended to limit the present disclosure. Any modification, equivalent replacement, improvement, etc. made within the spirit and principles of the present disclosure shall be included in the scope of protection of the present disclosure.

What is claimed is:

1. A manufacturing method of a display module, comprising:
providing a back plate and forming a first sub-metal layer on the back plate;
providing an epitaxial structure, wherein the epitaxial structure comprises a substrate and a semiconductor structure disposed on the substrate;
forming a planarization layer on a side of the semiconductor structure away from the substrate, and patterning the planarization layer to define a plurality of first via holes penetrating through the planarization layer;
forming a second sub-metal layer on the planarization layer, wherein the second sub-metal layer is electrically connected with the semiconductor structure through each of the plurality of first via holes;
bonding the epitaxial structure and the back plate through the first sub-metal layer and the second sub-metal layer, and removing the substrate in a bonded epitaxial structure; and
patterning the semiconductor structure to form a plurality of light-emitting units separated from one another, wherein a projection of one light-emitting unit on the back plate overlaps with a projection of one first via hole on the back plate.

2. The manufacturing method of the display module of claim 1, further comprising:
depositing a mask layer on the back plate, and patterning the mask layer to expose a part of the planarization layer between adjacent light-emitting units; and
etching the planarization layer, a bonded first sub-metal layer, and a bonded second sub-metal layer, under shield of a patterned mask layer.

3. The manufacturing method of the display module of claim 2, further comprising:
forming an insulating protection layer on the back plate;
patterning the insulating protection layer to expose a part of a surface of each of the plurality of light-emitting units away from the back plate; and
forming a conductive layer on the back plate, wherein the conductive layer is electrically connected with each of the plurality of light-emitting units through an exposed surface of each of the plurality of light-emitting units.

4. The manufacturing method of the display module of claim 2, further comprising:
before forming the planarization layer,
forming an ohmic contact layer on the side of the semiconductor structure away from the substrate; and
wherein etching the planarization layer, the bonded first sub-metal layer, and the bonded second sub-metal layer further comprises etching the ohmic contact layer.

5. The manufacturing method of the display module of claim 1, wherein removing the substrate in the bonded epitaxial structure comprises:
removing the substrate in the bonded epitaxial structure through a wet etching process.

6. A display module, comprising:
a back plate; and
a plurality of light-emitting units, wherein the plurality of light-emitting units are disposed on a surface of the back plate in an array, each of the plurality of light-emitting units comprises a metal reflection portion, a planarization portion, and a semiconductor structure portion stacked on the back plate in sequence, and the semiconductor structure portion is electrically connected with the metal reflection portion through a first via hole penetrating through the planarization portion.

7. The display module of claim 6, wherein each of the plurality of light-emitting units comprises an ohmic contact portion, the ohmic contact portion is formed between the planarization portion and the semiconductor structure portion, and the semiconductor structure portion is electrically connected with a second sub-metal layer through the ohmic contact portion and the first via hole.

8. The display module of claim 6, further comprising:
an insulating protection layer formed and covering on each of the plurality of light-emitting units.

9. The display module of claim 8, further comprising:
a conductive layer, wherein the conductive layer is formed on the insulating protection layer and is electrically connected with each of the plurality of light-emitting units through a plurality of second via holes penetrating through the insulating protection layer, and each of the plurality of light-emitting layer is connected with one another through the conductive layer.

10. The display module of claim 6, wherein the metal reflection portion comprises a first sub-metal layer and a second sub-metal layer stacked on the back plate in sequence.

11. The display module of claim 9, wherein the back plate comprises a plurality of first electrodes, and the plurality of first electrodes are electrically connected with the metal reflection portion.

12. The display module of claim 11, wherein the back plate comprises a plurality of second electrodes, and the plurality of second electrodes are electrically connected with the metal reflection portion.

13. The display module of claim 6, wherein the semiconductor structure portion comprises a first semiconductor structure portion, a light-emitting portion, and a second semiconductor structure portion which are stacked in sequence, and the first semiconductor structure portion is electrically connected with the metal reflection portion.

14. An electronic device, comprising a display module, wherein the display module comprises:
a back plate; and
a plurality of light-emitting units, wherein the plurality of light-emitting units are disposed on a surface of the back plate in an array, each of the plurality of light-emitting units comprises a metal reflection portion, a planarization portion, and a semiconductor structure portion stacked on the back plate in sequence, and the semiconductor structure portion is electrically connected with the metal reflection portion through a first via hole penetrating through the planarization portion.

15. The electronic device of claim 14, wherein each of the plurality of light-emitting units comprises an ohmic contact portion, the ohmic contact portion is formed between the planarization portion and the semiconductor structure portion, and the semiconductor structure portion is electrically connected with a second sub-metal layer through the ohmic contact portion and the first via hole.

16. The electronic device of claim 14, wherein the display module further comprises:
an insulating protection layer formed and covering on each of the plurality of light-emitting units.

17. The electronic device of claim 16, wherein the display module further comprises:
a conductive layer, wherein the conductive layer is formed on the insulating protection layer and is electrically connected with each of the plurality of light-emitting units through a plurality of second via holes penetrating through the insulating protection layer, and each of the plurality of light-emitting layer is connected with one another through the conductive layer.

18. The electronic device of claim 14, wherein the metal reflection portion comprises a first sub-metal layer and a second sub-metal layer stacked on the back plate in sequence.

19. The electronic device of claim 17, wherein the back plate comprises a plurality of first electrodes, and the plurality of first electrodes are electrically connected with the metal reflection portion.

20. The electronic device of claim 19, wherein the back plate comprises a plurality of second electrodes, and the plurality of second electrodes are electrically connected with the metal reflection portion.
